(19) United States
(12) Patent Application Publication
(10) Pub. No.: US 2012/0154998 A1
(43) Pub. Date: Jun. 21, 2012

(54) ELECTRONIC APPARATUS

(75) Inventors: Junichi NONOMURA, Ome-shi (JP); Nobuyuki HOSOYA, Ome-shi (JP)

(73) Assignee: KABUSHIKI KAISHA TOSHIBA, Tokyo (JP)

(21) Appl. No.: 13/295,649

(22) Filed: Nov. 14, 2011

(30) Foreign Application Priority Data
Dec. 21, 2010 (JP) 2010-284749

(51) Int. Cl. H05K 5/00

(52) U.S. Cl. 361/679.01

(57) ABSTRACT

According to one embodiment, an electronic apparatus includes a housing and a stylus guide provided in the housing. The stylus guide allows the insertion of a stylus, and has a plurality of convex portions. The convex portions are configured to come into slidable contact with the stylus at positions spaced apart from each other in the axial direction of the stylus.

### CROSS-REFERENCE TO RELATED APPLICATIONS

This application is based upon and claims the benefit of priority from Japanese Patent Application No. 2010-284749, filed Dec. 21 2010; the entire contents of which are incorporated herein by reference.

### FIELD

Embodiments described herein relate generally to an electronic apparatus including a stylus guide into which a stylus is inserted.

### BACKGROUND

For example, an electronic apparatus having a handwritten character recognition function includes a stylus receptacle configured to removably accommodate a stylus in the housing. The stylus receptacle is a tunnel-like cavity, which extends within the housing in the direction of insertion of the stylus.

There is a clearance between the stylus and the inner surface of the stylus receptacle when the stylus is accommodated in the stylus receptacle. For this reason, when the electronic apparatus into which the stylus has been inserted is carried around, the stylus may rattle in the stylus receptacle.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of a portable computer according to the first embodiment;

FIG. 2 is an exemplary perspective view showing a state in which a stylus for handwriting input is inserted in the insertion opening of a first housing;

FIG. 3 is an exemplary plan view showing a state in which a dummy unit is fixed to the top cover of the first housing;

FIG. 4 is an exemplary perspective view showing a state in which the dummy unit is fixed to the top cover of the first housing;

FIG. 5 is an exemplary sectional view of a main module;

FIG. 6 is an exemplary perspective view of the dummy unit;

FIG. 7 is an exemplary perspective view of a stylus guide;

FIG. 8 is an exemplary perspective view of the stylus guide viewed from the side opposite to that shown in FIG. 7;

FIG. 9 is an exemplary plan view showing a state in which the stylus is inserted in the stylus guide;

FIG. 10 is an exemplary enlarged plan view of a portion F10 in FIG. 9;

FIG. 11 is an exemplary plan view showing a state in which the stylus guide is slid to the first position, together with the stylus;

FIG. 12 is an exemplary plan view showing a state in which the stylus guide is slid to the second position, together with the stylus;

FIG. 13 is an exemplary plan view showing the positional relationship between the first and second convex portions of a stylus guide and a stylus in the second embodiment;

FIG. 14 is an exemplary perspective view of a stylus guide used in the third embodiment;

FIG. 15 is an exemplary sectional view showing the positional relationship between a vibration-proofing member bonded to the stylus guide and a stylus;

FIG. 16 is an exemplary perspective view of a stylus guide used in the fourth embodiment;

FIG. 17 is an exemplary sectional view showing the positional relationship between a vibration-proofing member bonded to the stylus guide and a stylus; and

FIG. 18 is an exemplary plan view showing a state in which a stylus is inserted in a stylus guide used in the fifth embodiment.

### DETAILED DESCRIPTION

Various embodiments will be described hereinafter with reference to the accompanying drawings. In general, according to one embodiment, an electronic apparatus includes a housing and a stylus guide provided in the housing. The stylus guide allows the insertion of a stylus, and has a plurality of convex portions. The convex portions are configured to come into slidable contact with the stylus at positions spaced apart from each other in the axial direction of the stylus.

### First Embodiment

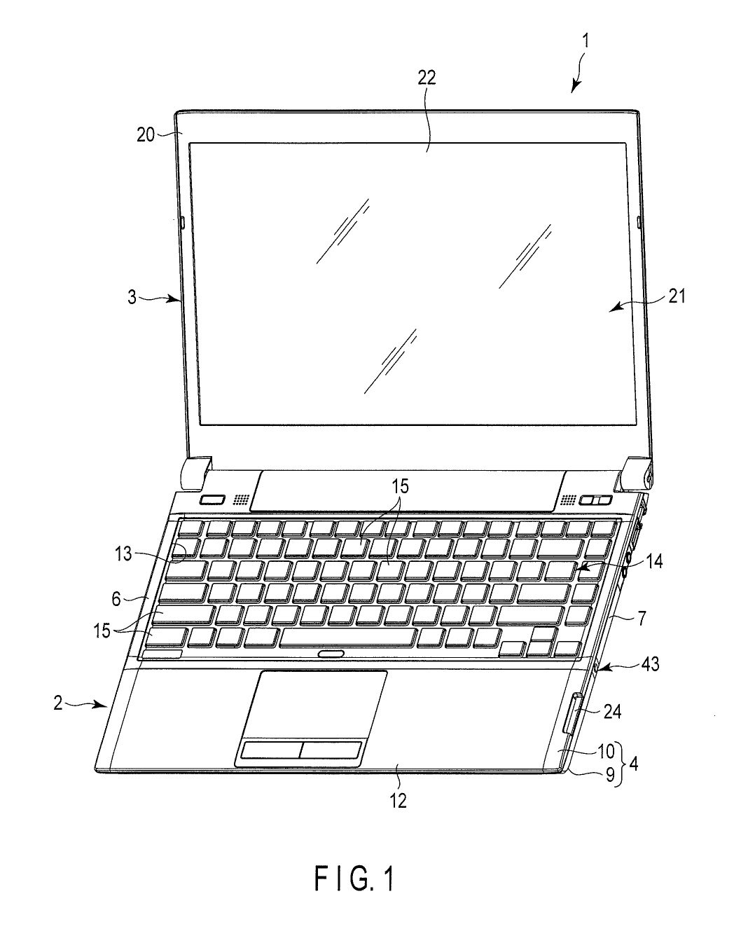

The first embodiment will be described below with reference to FIGS. 1 to 12.

FIG. 1 shows a portable computer 1 as an example of an electronic apparatus. The portable computer 1 includes a main module 2 and a display module 3. The main module 2 includes a first housing 4. The first housing 4 is a flat box having a bottom wall 5, an upper wall 6, and left and right sidewalls 7 (only the right sidewall is shown).

When the portable computer 1 is placed on, for example, a desk, the bottom wall 5 faces the upper surface of the desk. The bottom wall 5 has a front end portion 5a curved upward to the first housing 4 in an arcuated form. The upper wall 6 faces the bottom wall 5. The front end edge of the upper wall 6 abuts on the upper edge of the front end portion 5a of the bottom wall 5. The sidewall 7 extends vertically from the bottom wall 5 so as to extend astride a side edge of the bottom wall 5 and a side edge of the upper wall 6.

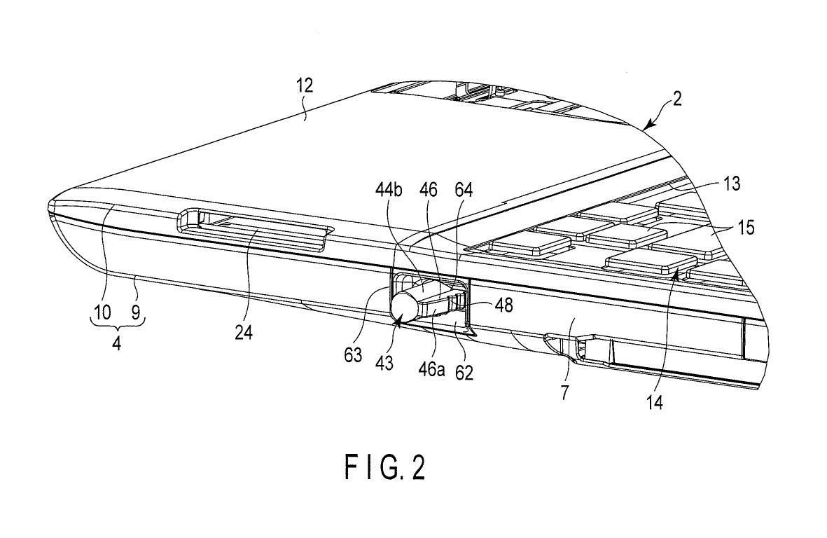

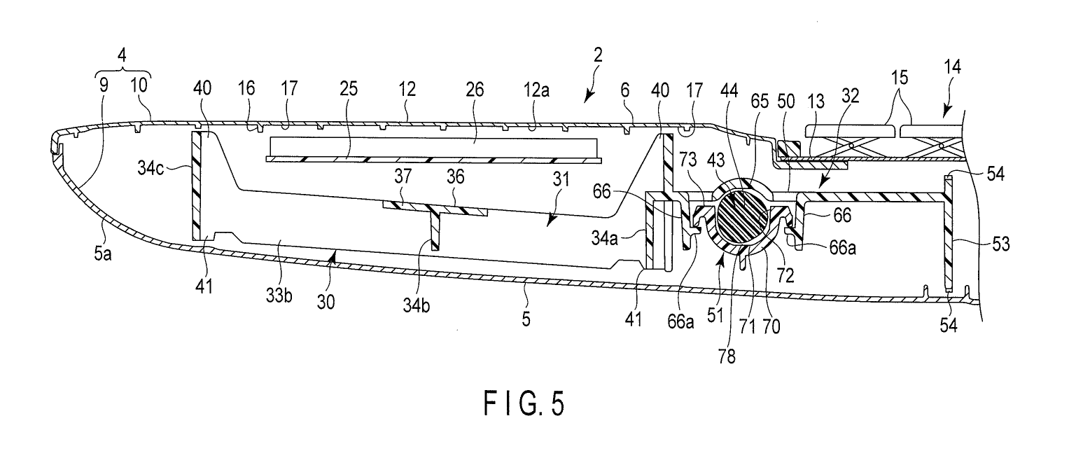

As shown in FIGS. 2 and 5, the first housing 4 includes a base 9 and a top cover 10. The base 9 includes the bottom wall 5 and the sidewall 7. The top cover 10 includes the upper wall 6. The first housing 4 is assembled by placing the top cover 10 on the base 9.

As shown in FIGS. 1, 2 and 5, the upper wall 6 of the first housing 4 includes a palm rest 12 and a keyboard mounting portion 13. The palm rest 12 extends in the widthwise direction of the first housing 4 at the front half portion of the upper wall 6. The keyboard mounting portion 13 is formed by a rectangular recess sinking from the palm rest 12, and is located behind the palm rest 12.

A keyboard 14 is mounted in the keyboard mounting portion 13. The keyboard 14 has a plurality of key tops 15. The upper surfaces of the key tops 15 are located in the same plane as the upper surface of the palm rest 12, and are exposed on the upper wall 6 of the first housing 4.

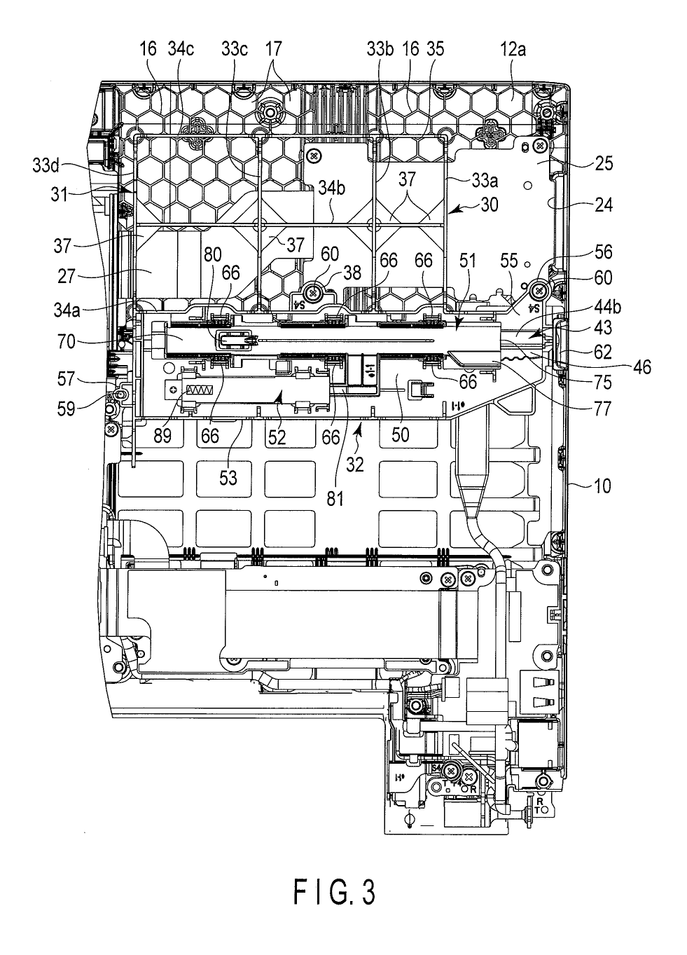

As shown in FIGS. 3, 4 and 5, the palm rest 12 has an inner surface 12a exposed to the inside of the first housing 4. A plurality of ribs 16 arranged in the form of a honeycomb are integral with the inner surface 12a of the palm rest 12. The ribs 16 are components configured to reinforce the palm rest 12 from the inside of the first housing 4, and protrude downward slightly from the inner surface 12a of the palm rest 12. The ribs 16 define a plurality of hexagonal areas 17 on the inner surface 12a of the palm rest 12. The areas 17 cover the entire area of the inner surface 12a of the palm rest 12 and adjoin each other.

As shown in FIG. 1, the display module 3 includes a second housing 20 and a liquid crystal display device 21 accommodated in the second housing 20. The second housing 20 is a flat box of almost the same size as the first housing 4. The liquid crystal display device 21 includes a transparent touch panel 22 used for inputting information. The touch panel 22 is stacked on the liquid crystal display panel, and is exposed outside the second housing 20 from its front surface.

The display module 3 is supported on the rear end of the first housing 4 and is pivotal between a closed position and an open position. At the closed position, the display module 3 lies on the first housing 4 so as to cover the palm rest 12 and the keyboard 14. At the open position, the display module 3 extends vertically from the rear end portion of the first housing 4 so as to expose the palm rest 12, the keyboard 14, and the touch panel 22.

As shown in FIGS. 1 and 2, the first housing 4 includes a card slot 24 to allow, for example, the insertion and removal of an SD memory card. The card slot 24 opens in the corner portion of the first housing 4 which is defined by the right end portion of the palm rest 12 and the upper portion of the sidewall 7.

As shown in FIGS. 3, 4 and 5, a rigid printed circuit board 25 is fixed to the right end portion of the inner surface 12a of the palm rest 12 with screws. A card holder 26 is mounted on the printed circuit board 25. The card holder 26 holds the SD memory card inserted from the card slot 24, and has terminals to which the SD memory card is electrically connected. The card holder 26 is placed in the gap between the printed circuit board 25 and the inner surface 12a of the palm rest 12, and is adjacent to the card slot 24.

A flexible printed wiring board 27 is connected to the printed circuit board 25. The flexible printed wiring board 27 extends from the printed circuit board 25 along the inner surface 12a of the palm rest 12, and is electrically connected to a motherboard accommodated in the first housing 4.

As the portable computer 1 according to the first embodiment, there is prepared a premium model having an optical disk drive mounted in the first housing 4 or a basic model from which an optical disk drive is omitted. The portable computer 1 shown in FIG. 1 is a basic model. The basic model has a dummy unit 30 made of a synthetic resin and detachably accommodated in an implementation space in the first housing 4 in place of an optical disk drive.

As shown in FIGS. 3, 4 and 6, the dummy unit 30 includes a frame structure 31 and a stylus holder 32. The frame structure 31 has a size corresponding to the optical disk drive. The frame structure 31 includes first to fourth vertical crosspieces 33a, 33b, 33c and 33d and first to third horizontal crosspieces 34a, 34b and 34c.

The first to fourth vertical crosspieces 33a, 33b, 33c and 33d extend in the depth direction of the first housing 4, and are parallelly arranged at intervals in the widthwise direction of the first housing 4. The first to third horizontal crosspieces 34a, 34b and 34c extend in the widthwise direction of the first housing 4, and are parallelly arranged at intervals in the depth direction of the first housing 4. For this reason, the first to fourth vertical crosspieces 33a, 33b, 33c and 33d and the first to third horizontal crosspieces 34a, 34b and 34c are assembled in a lattice pattern so as to be perpendicular to each other.

According to the first embodiment, the first and fourth vertical crosspieces 33a and 33d and the first and third horizontal crosspieces 34a and 34c constitute a rectangular outer frame 35 in cooperation with each other. The outer frame 35 defines the outer shape of the frame structure 31.

The frame structure 31 includes four intersecting portions 36 where the second horizontal crosspiece 34b and the first to fourth vertical crosspieces 33a, 33b, 33c and 33d intersect each other. The intersecting portions 36 are lined in the widthwise direction of the first housing 4.

A reinforcing plate 37 reinforces each intersecting portion 36 of the frame structure 31. The reinforcing plates 37 are placed astride the upper edges of the second horizontal crosspiece 34b and first vertical crosspiece 33a, the upper edges of the second horizontal crosspiece 34b and second vertical crosspiece 33b, the upper edges of the second horizontal crosspiece 34b and third vertical crosspiece 33c, and the upper edges of the second horizontal crosspiece 34b and fourth vertical crosspiece 33d, respectively.

A boss portion 38 is integrally formed with the first horizontal crosspiece 34a. The boss portion 38 protrudes from an intermediate portion of the first horizontal crosspiece 34a along the longitudinal direction toward the second horizontal crosspiece 34b so as to face the inner surface 12a of the palm rest 12.

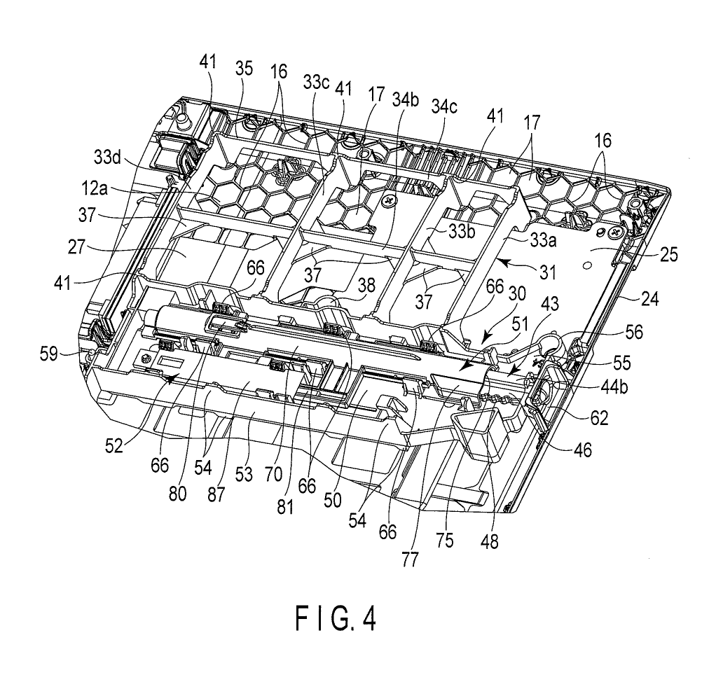

As shown in FIGS. 4, 5 and 6, the frame structure 31 includes a plurality of first projections 40 and a plurality of second projections 41. The first projections 40 protrude from the first horizontal crosspiece 34a, the third horizontal crosspiece 34c, and the first to fourth vertical crosspieces 33a to 33d toward the inner surface 12a of the palm rest 12. The first projections 40 are arranged at intervals in the longitudinal directions of the first and third horizontal crosspieces 34a and 34c, and are spaced apart from each other in the longitudinal directions of the first to fourth vertical crosspieces 33a to 33d.

The second projections 41 protrude from the first and third horizontal crosspieces 34a and 34c toward the inner surface of the bottom wall 5 of the first housing 4. The second projections 41 are arranged at intervals in the longitudinal directions of the first and third horizontal crosspieces 34a and 34c.

The stylus holder 32 of the dummy unit 30 is a component configured to removably hold a stylus 43 made of a synthetic resin. The stylus 43 is an example of a pen-like tool for the execution of input operation by pressing the touch panel 22, and can also be described as an insertable member.

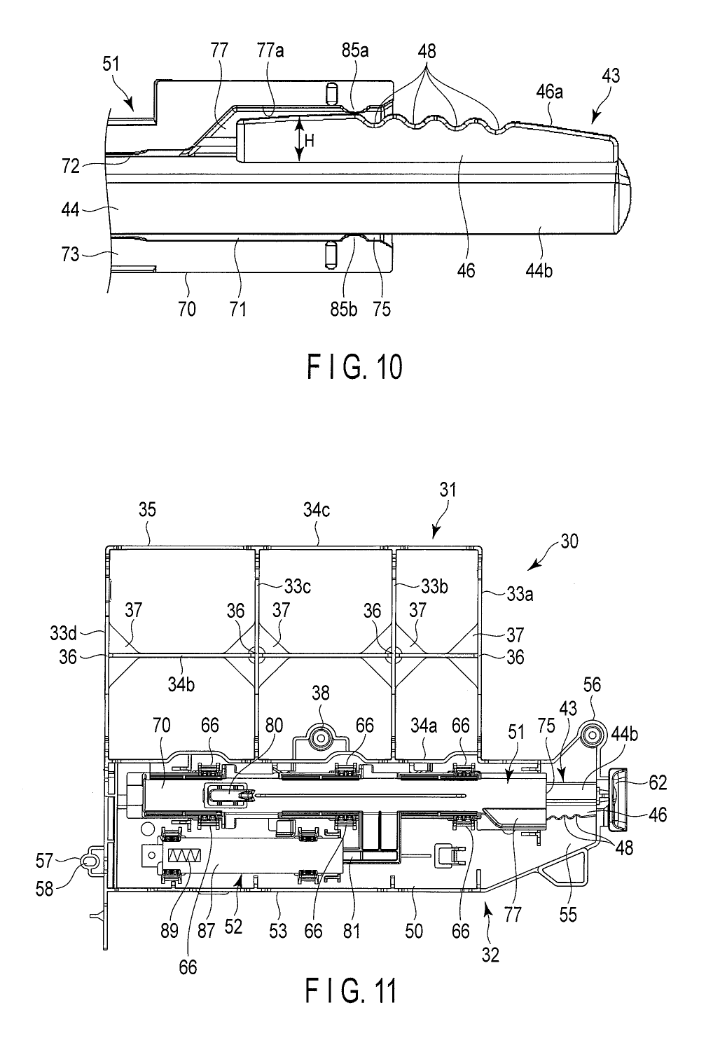

As shown in FIGS. 9 and 10, the stylus 43 includes a linear stylus shaft 44, a stylus tip 45, and a projection portion 46. The stylus shaft 44 has a first end portion 44a and a second end portion 44b.

The first end portion 44a is tapered narrower toward its tip. The stylus tip 45 is smaller in diameter than the stylus shaft 44 and coaxially protrudes from the distal end of the first end portion 44a of the stylus shaft 44. For this reason, the first end portion 44a of the stylus shaft 44 gradually increases in diameter with distance from the stylus tip 45. The diameter of the first end portion 44a becomes almost uniform at a portion spaced apart from the stylus tip 45 by a predetermined distance L.

An engagement groove 47 is formed in the outer surface of the first end portion 44a. The engagement groove 47 is continuous in the circumferential direction of the stylus shaft 44, and is located at the portion, of the first end portion 44a, which becomes uniform in diameter at first. In other words, the engagement groove 47 is located closer to the stylus tip 45 than the intermediate portion of the stylus shaft 44 along the axial direction.

The second end portion 44b of the stylus shaft 44 is located on the side opposite to the stylus tip 45. The diameter of the second end portion 44b is almost equal to the maximum diameter of the first end portion 44a.

The projection portion 46 is integrally formed with the second end portion 44b of the stylus shaft 44. The projection portion 46 protrudes as a fin from the outer surface of the second end portion 44b so as to extend in the axial direction of the stylus shaft 44.

As shown in FIG. 10, the projection portion 46 has an outer peripheral edge portion 46a. The outer peripheral edge portion 46a is curved in an arcuated form between the front and rear ends of the projection portion 46 in a direction to separate from the outer surface of the second end portion 44b. For this reason, a height H of the projection portion 46 relative to the second end portion 44b is maximum at the intermediate portion between the front and rear ends of the projection portion 46.

A plurality of recesses 48 are formed in the intermediate portion of the outer peripheral edge portion 46a of the projection portion 46. The recesses 48 allow the user to engage the fingertips on them, and are lined at intervals in the axial direction of the stylus shaft 44.

As shown in FIGS. 3 to 6, the stylus holder 32 is integrated with the frame structure 31. The stylus holder 32 includes a holder main body 50 as a receptacle, a stylus guide 51 as a moving portion, and a catch mechanism 52.

The holder main body 50 is integrally formed with the first horizontal crosspiece 34a of the frame structure 31. The holder main body 50 is an elongated plate extending in the widthwise direction of the first housing 4, and protrudes around the frame structure 31.

The holder main body 50 has a reinforcing wall 53. The reinforcing wall 53 extends vertically from the peripheral edge of the holder main body 50 toward the bottom wall 5 of the first housing 4, and surrounds the holder main body 50 in cooperation with the first horizontal crosspiece 34a. A plurality of third projections 54 are formed on the upper and lower edges of the reinforcing wall 53. The third projections 54 are arranged at intervals.

The holder main body 50 has an extending portion 55. The extending portion 55 protrudes around the frame structure 31 more than the first vertical crosspiece 33a of the frame structure 31. A boss portion 56 is integrally formed with the extending portion 55. The boss portion 56 protrudes from the extending portion 55 so as to face the inner surface 12a of the palm rest 12.

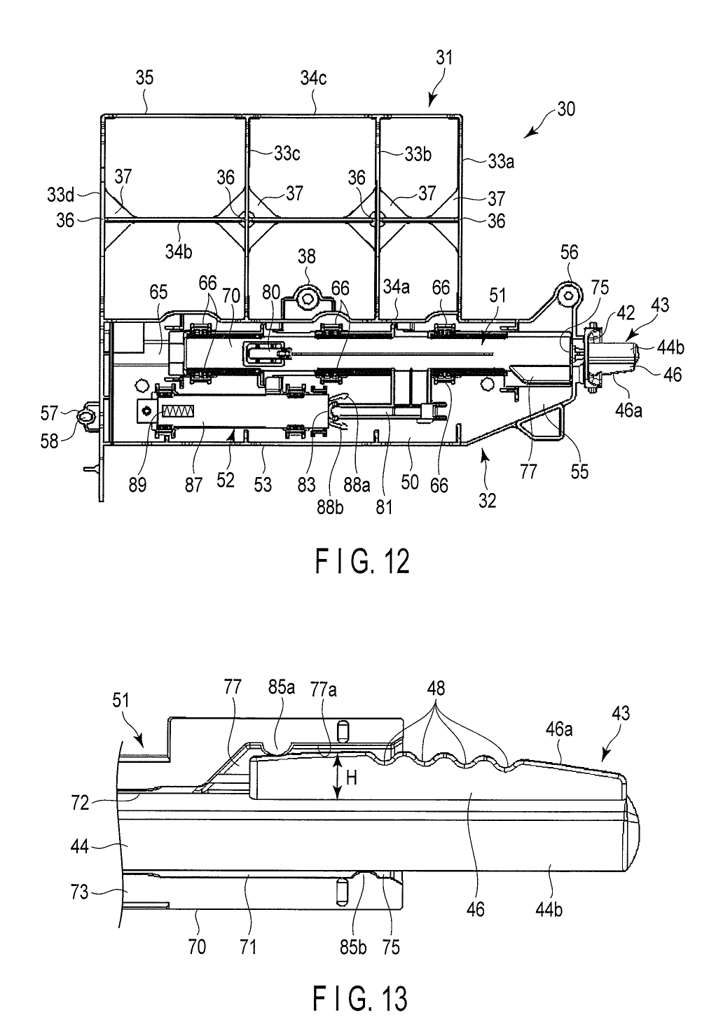

A positioning portion 57 shown in FIGS. 11 and 12 is integrally formed with the holder main body 50. The positioning portion 57 is located on the side opposite to the extending portion 55 and has an elongated engagement hole 58.

As shown in FIGS. 3 and 4, a convex portion 59 protruding from the inner surface 12a of the palm rest 12 is fitted in the engagement hole 58 of the positioning portion 57. With this fitting, the dummy unit 30 is roughly positioned relative to the palm rest 12. The boss portion 38 of the frame structure 31 and the boss portion 56 of the stylus holder 32 are fixed to the inner surface 12a of the palm rest 12 with screws 60.

For this reason, as shown in FIG. 5, the dummy unit 30 is accommodated in an implementation space in the first housing 4 while being suspended from the inner surface 12a of the right end portion of the palm rest 12. The frame structure 31 of the dummy unit 30 is interposed between the bottom wall 5 of the first housing 4 and the palm rest 12 to reinforce the first housing 4 from inside.

More specifically, each first projection 40 of the frame structure 31 abuts against the inner surface 12a of the palm rest 12 at a position corresponding to the area 17 surrounded by the honeycomb of ribs 16 or faces the inner surface 12a of the palm rest 12 through, for example, a slight gap of about 1 mm. Likewise, each second projection 41 of the frame structure 31 abuts against the inner surface of the bottom wall 5 of the first housing 4 or faces the inner surface of the bottom wall 5 through, for example, a slight gap of about 1 mm.

With this arrangement, when an external force acts on the first housing 4 to press the right end portion of the palm rest 12 from above, the frame structure 31 supports the palm rest 12 from below to prevent the deformation of the palm rest 12.

In the first embodiment, the printed circuit board 25 having the card holder 26 is accommodated in the gap between the second horizontal crosspiece 34b and first and second vertical crosspieces 33a and 33b of the frame structure 31 and the inner surface 12a of the palm rest 12. The flexible printed wiring board 27 connected to the printed circuit board 25 is wired through the gap between the frame structure 31 and the inner surface 12a of the palm rest 12.

In this case, as shown in FIGS. 4 and 5, the first projections 40 of the frame structure 31 support the palm rest 12, around the printed circuit board 25, from below. Even if, therefore, the right end portion of the palm rest 12 is pressed from above, the palm rest 12 becomes difficult to deform in a concave form. This can prevent the palm rest 12 and the card holder 26 from interfering with each other.

While the dummy unit 30 is fixed to the inner surface 12a of the palm rest 12, the holder main body 50 of the stylus holder 32 is located in an area extending from the rear portion of the right end portion of the palm rest 12 to a position below the keyboard mounting portion 13. The holder main body 50 extends from the right sidewall 7 of the first housing 4 in the widthwise direction of the first housing 4. The reinforcing wall 53 of the holder main body 50 is interposed between the keyboard mounting portion 13 and the bottom wall 5 of the first housing 4 to reinforce the first housing 4 from inside.

That is, the distal ends of the third projections 54 of the reinforcing wall 53 abut against the inner surface of the keyboard mounting portion 13 and the inner surface of the bottom wall 5 or face the inner surface 12a of the palm rest 12 and the inner surface of the bottom wall 5 through, for example, a slight gap of about 1 mm.

With this arrangement, when an external force acts on the first housing 4 to press the keyboard 14 from above, the reinforcing wall 53 of the stylus holder 32 supports the keyboard mounting portion 13 from below to prevent the deformation of the first housing 4.

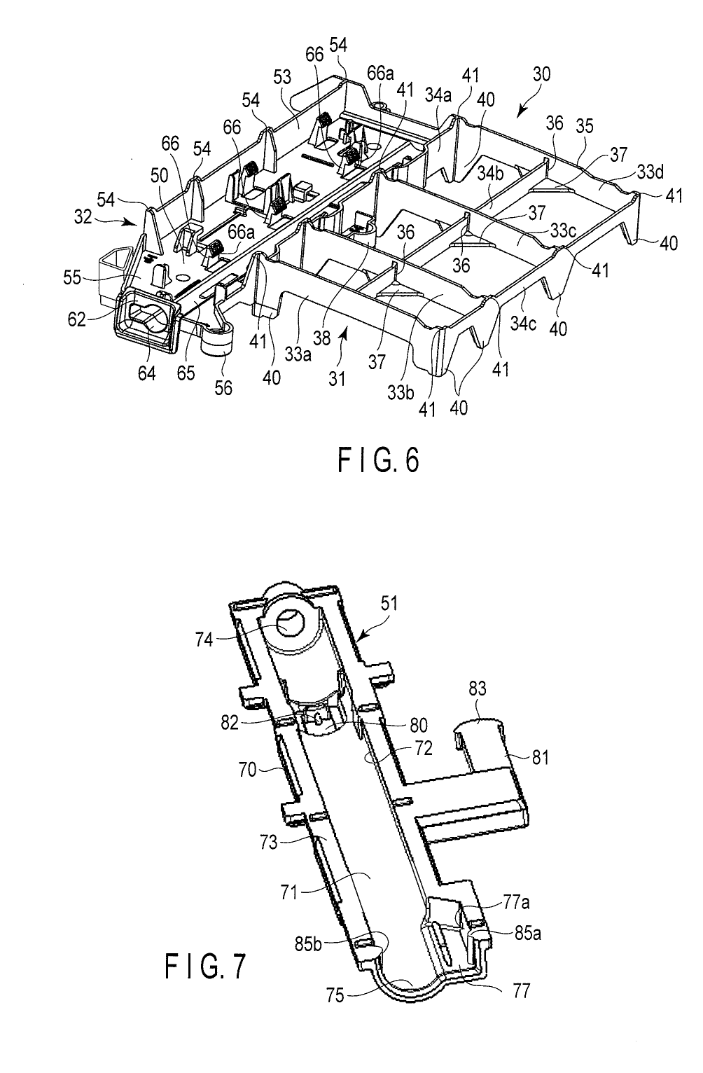

As shown in FIGS. 4 and 6, the extending portion 55 of the holder main body 50 includes an end wall 62. The end wall 62 is fitted in an opening portion 63 provided in the right sidewall 7 of the first housing 4. In other words, the end wall 62 is exposed from the opening portion 63 to the outside of the first housing 4, and is part of exterior elements forming the first housing 4. An insertion opening 64 which allows the insertion and removal of the stylus 43 is formed in the end wall 62. The insertion opening 64 is opened in the implementation space inside the first housing 4.

As shown in FIGS. 5 and 6, the holder main body 50 has a recess portion 65 bent in an arcuated form. The recess portion 65 serves to receive the stylus shaft 44 of the stylus 43, and linearly extends in the longitudinal direction of the holder main body 50. One end of the recess portion 65 is continuous with the insertion opening 64 through the extending portion 55.

A plurality of support pieces 66 are integrally formed with the holder main body 50. The support pieces 66 protrude from the holder main body 50 and have pawls 66a at their protrusion ends. The support pieces 66 face each other through the recess portion 65 and are arranged at intervals in the longitudinal direction of the holder main body 50.

The stylus guide 51 is formed by, for example, a synthetic resin. As shown in FIGS. 7, 8 and 9, the stylus guide 51 includes a main body 70 extending in the axial direction of the stylus 43. The main body 70 is semi-cylindrical, and includes a concave portion 71 which the stylus shaft 44 of the stylus 43 enters, and a slit 72 which is continuous with the concave portion 71. The slit 72 opens in the outer surface of the main body 70 so as to extend in the axial direction of the stylus shaft 44. This allows the main body 70 of the stylus guide 51 to elastically deform in a direction to increase the width of the slit 72. The width of the slit 72 coincides with the radial direction of the stylus shaft 44.

The main body 70 of the stylus guide 51 includes a slide guide surface 73 surrounding the slit 72, an insertion hole 74 which the stylus tip 45 of the stylus 43 enters, and a stylus insertion portion 75 located on the side opposite to the insertion hole 74.

The stylus insertion portion 75 has a receiving portion 77 which the projection portion 46 of the stylus 43 enters. The receiving portion 77 has an inner surface 77a facing the outer peripheral edge portion 46a of the projection portion 46 of the stylus 43. The inner surface 77a extends in the longitudinal direction of the main body 70, and faces a portion, of the inner surface of the concave portion 71, which is continuous with the slide guide surface 73.

The stylus guide 51 is fitted between the support pieces 66 while taking a posture in which the slit 72 of the main body 70 faces the recess portion 65 of the holder main body 50. As shown in FIGS. 4 and 5, this makes the pawls 66a of the support pieces 66 be slidably caught on the main body 70 of the stylus guide 51 from the side opposite to the recess portion 65. This therefore makes the stylus guide 51 be slidably caught between the pawls 66a of the support pieces 66 and the lower surface of the holder main body 50 and also makes the slide guide surface 73 of the stylus guide 51 face the lower surface of the holder main body 50.

As a result, the holder main body 50 movably holds the stylus guide 51 so as to allow it to slide in the widthwise direction of the first housing 4. The concave portion 71 of the stylus guide 51 faces the recess portion 65 of the holder main body 50. The concave portion 71 and the recess portion 65 define a tunnel-like receptacle 78 in cooperation with each other. The receptacle 78 communicates with the insertion opening 64 of the holder main body 50.

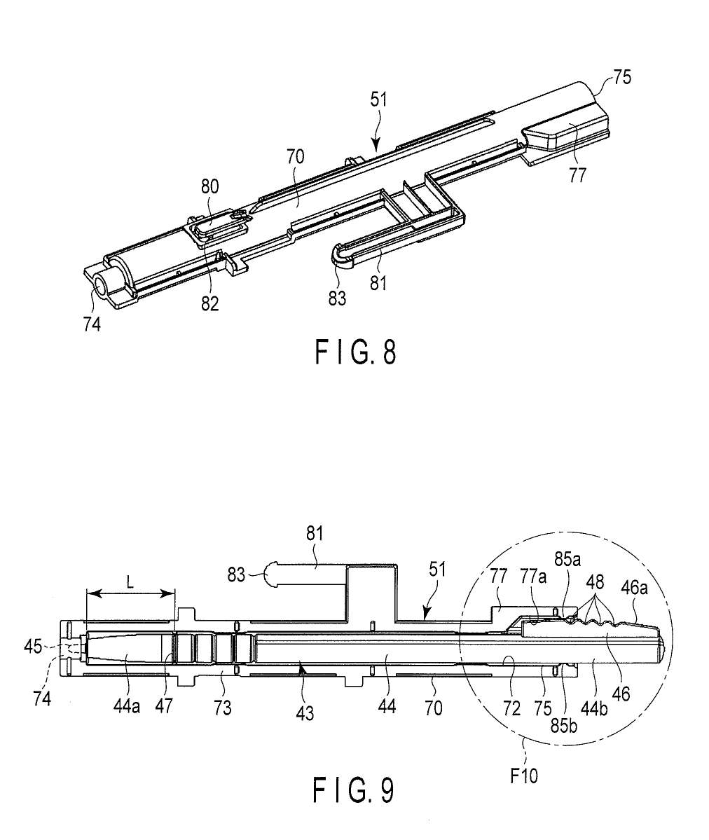

As shown in FIGS. 7 and 8, the stylus guide 51 includes an engagement piece 80 and an arm portion 81. The engagement piece 80 is integrally formed with the main body 70 of the stylus guide 51 at a position closer to the insertion hole 74 than the intermediate portion of the stylus guide 51 along the longitudinal direction. The engagement piece 80 has an engagement projection 82 protruding into the concave portion 71. The engagement projection 82 is an example of the first engagement portion. The engagement piece 80 is elastically deformable in the direction in which the engagement projection 82 retreats from the concave portion 71.

The arm portion 81 branches off from the intermediate portion of the stylus guide 51 along the longitudinal direction and extends in the direction of the insertion hole 74 of the stylus guide 51. The arm portion 81 is parallel to the stylus guide 51. The distal end of the arm portion 81 serves as an arrowhead-like fitting portion 83 which spreads wider than the arm portion 81.

The stylus 43 is inserted from the insertion opening 64 into the receptacle 78 through the stylus insertion portion 75 of the stylus guide 51. When the engagement groove 47 of the stylus shaft 44 reaches the position of the engagement projection 82 of the stylus guide 51 upon insertion of the stylus 43, the engagement projection 82 is elastically caught in the engagement groove 47.

This presses the first end portion 44a of the stylus shaft 44 against the inner surface of the recess portion 65 of the holder main body 50. As a consequence, the stylus shaft 44 is integrally coupled to the stylus guide 51 to make the stylus guide 51 move together with the stylus 43.

More specifically, FIG. 9 shows the relationship between the stylus guide 51 and the stylus 43 when the engagement projection 82 of the stylus guide 51 is caught in the engagement groove 47 of the stylus shaft 44. As shown in FIG. 9, when the stylus 43 is integrally coupled to the stylus guide 51, the stylus tip 45 of the stylus 43 enters the insertion hole 74 of the stylus guide 51. At the same time, the second end portion 44b of the stylus shaft 44 having the projection portion 46 protrudes outside the stylus guide 51 through the stylus insertion portion 75 of the stylus guide 51.

In the first embodiment, the stylus guide 51 can move between the first position and the second position, together with the stylus 43. FIG. 11 shows a state in which the stylus guide 51 is moved to the first position. At the first position, the stylus insertion portion 75 of the stylus guide 51 is located far from the insertion opening 64, and the second end portion 44b of the stylus shaft 44 having the projection portion 46 is located between the stylus insertion portion 75 and the insertion opening 64.

The stylus 43 is therefore accommodated in the first housing 4, and the second end portion 44b of the stylus shaft 44 stays in the opening end of the insertion opening 64 without protruding from the first housing 4.

FIG. 12 shows a state in which the stylus guide 51 is moved to the second position. At the second position, the stylus insertion portion 75 of the stylus guide 51 is located immediately before the end wall 62 of the holder main body 50, and the second end portion 44b of the stylus shaft 44 having the projection portion 46 protrudes outside the first housing 4 through the insertion opening 64. FIG. 2 shows a state in which the second end portion 44b of the stylus shaft 44 protrudes outside the first housing 4 through the insertion opening 64.

As shown in FIGS. 9 and 10, while the stylus 43 is coupled to the stylus guide 51, the front half portion of the projection portion 46 of the stylus shaft 44 is inserted in the receiving portion 77 of the stylus guide 51. A first convex portion 85a is integrally formed with the inner surface 77a of the receiving portion 77. A second convex portion 85b is integrally formed with the inner surface of the stylus insertion portion 75 which faces the receiving portion 77. The first and second convex portions 85a and 85b are an example of the second engagement portion. The first and second convex portions 85a and 85b each have a distal end curved in an arcuated form. In addition, the first and second convex portions 85a and 85b face each other in the radial direction of the stylus shaft 44 at a position closer to the side opposite to the stylus tip 45 than the intermediate portion of the stylus shaft 44 along the axial direction.

The distal end of the first convex portion 85a located on the receiving portion 77 is in slidable contact with the outer peripheral edge portion 46a of the projection portion 46. According to the first embodiment, the distal end of the first convex portion 85a is in contact with the outer peripheral edge portion 46a of the projection portion 46 at a position immediately before the first recess 48 near the front end of the projection portion 46, as shown in FIG. 10. At a position corresponding to the first recess 48 of the projection portion 46, a height H of the projection portion 46 is maximum. For this reason, the first convex portion 85a is in contact with the outer peripheral edge portion 46a of the projection portion 46 at the position where the height H of the projection portion 46 is maximum.

On the other hand, the second convex portion 85b of the inner surface of the stylus insertion portion 75 is in slidable contact with the outer surface of the second end portion 44b of the stylus shaft 44. This makes the first and second convex portions 85a and 85b clamp and hold the stylus shaft 44 and the projection portion 46 at a position immediately before the stylus shaft 44 protrudes outside the stylus guide 51 through the stylus insertion portion 75.

The catch mechanism 52 is an example of a locking mechanism for locking the stylus guide 51 at the first position or releasing the stylus guide 51. The catch mechanism 52 includes a case 87 and a pair of clamping pawls 88a and 88b supported by the case 87.

The case 87 is an elongated box extending in the moving direction of the stylus guide 51, and is fixed to the holder main body 50 so as to be adjacent to the stylus guide 51. The arm portion 81 of the stylus guide 51 is inserted into the case 87 from one end of the case 87 along the longitudinal direction. As shown in FIG. 12, while the stylus guide 51 is moved to the second position, the arm portion 81 is pulled out of the case 87, and the fitting portion 83 of the distal end of the arm portion 81 faces one end of the case 87.

When the stylus guide 51 is moved to the second position, the clamping pawls 88a and 88b are pressed by a spring 89 to protrude outside the case 87 through one end of the case 87. The fitting portion 83 of the distal end of the arm portion 81 is interposed between the clamping pawls 88a and 88b.

When the stylus guide 51 is moved from the second position toward the first position, the fitting portion 83 of the stylus guide 51 pushes the clamping pawls 88a and 88b into the case 87 against the spring 89. As the fitting portion 83 pushes the clamping pawls 88a and 88b, the clamping pawls 88a and 88b pivot in a direction to approach each other, thereby clamping the fitting portion 83. When the stylus guide 51 reaches the first position, the clamping pawls 88a and 88b are held in the case 87 so as not to be movable. This locks the stylus guide 51 at the first position.

In the portable computer 1 having the above arrangement, while the stylus 43 is removed outside the first housing 4 from the receptacle 78 of the stylus holder 32, the stylus guide 51 is moved to the second position shown in FIG. 12.

When the stylus 43 is inserted into the insertion opening 64 from the stylus tip 45, the stylus shaft 44 of the stylus 43 is guided into the receptacle 78 through the stylus insertion portion 75 of the stylus guide 51. When the stylus tip 45 enters the insertion hole 74 of the stylus guide 51 upon insertion of the stylus 43, the engagement projection 82 of the stylus guide 51 is elastically caught in the engagement groove 47 of the stylus shaft 44. This makes the stylus guide 51 start moving from the second position toward the first position following the insertion of the stylus 43.

When the stylus guide 51 is moved from the second position toward the first position, the arm portion 81 of the stylus guide 51 is pushed into the case 87 of the catch mechanism 52. When the stylus guide 51 reaches the first position, the clamping pawls 88a and 88b of the catch mechanism 52 are held in the case 87 so as not be movable while clamping the fitting portion 83 of the arm portion 81.

As a consequence, the stylus 43 is accommodated in the receptacle 78 of the first housing 4. While the stylus 43 is accommodated in the receptacle 78, an end face continuous with the projection portion 46 of the stylus shaft 44 is only exposed to the insertion opening 64. It is therefore impossible to pick up the stylus shaft 44 with the fingers and remove it from the receptacle 78. This makes it possible to prevent the stylus 43 from being stolen.

When removing the stylus 43 from the receptacle 78, the user presses the end face of the stylus shaft 44, which is exposed from the insertion opening 64, with a fingertip. As a consequence, the clamping pawls 88a and 88b are released from the case 87, and the spring 89 presses the clamping pawls 88a and 88b toward one end of the case 87. This pressing operation pushes the arm portion 81 outside the case 87 from one end of the case 87. Therefore, the stylus guide 51 moves from the first position toward the second position following the arm portion 81.

The clamping pawls 88a and 88b further protrude outside the case 87 from one end of the case 87 and pivot in a direction to separate from each other. This makes the clamping pawls 88a and 88b release from the fitting portion 83, thus releasing the stylus guide 51 from the catch mechanism 52.

When the stylus guide 51 reaches the second position, the second end portion 44b of the stylus shaft 44 having the projection portion 46 protrudes outside the first housing 4 through the insertion opening 64. This makes it possible for the user to remove the stylus 43 from the receptacle 78 by picking up and pulling the second end portion 44b of the stylus shaft 44 with the fingertips.

With this arrangement, while the engagement projection 82 of the stylus guide 51 is caught in the engagement groove 47 of the stylus 43, the outer surface of the first end portion 44a of the stylus shaft 44 is pressed against the inner surface of the recess portion 65 of the holder main body 50.

At the same time, the second end portion 44b and projection portion 46 of the stylus shaft 44 are clamped between the first convex portion 85a and second convex portion 85b of the stylus guide 51 at a position immediately before the protrusion of the second end portion 44b of the stylus shaft 44 from the stylus guide 51 through the stylus insertion portion 75.

This makes the stylus guide 51 hold the stylus shaft 44 of the stylus 43 at a position separated in the axial direction of the stylus shaft 44. This can suppress the backlash of the stylus 43 and prevent the production of annoying sounds accompanying the vibration of the stylus 43 even if the user carries the portable computer 1 while, for example, the stylus 43 is accommodated in the receptacle 78.

The engagement projection 82 of the stylus guide 51 is elastically caught in the engagement groove 47 of the stylus shaft 44 at a position closer to the stylus tip 45 than the intermediate portion of the stylus shaft 44 along the axial direction. For this reason, the engagement projection 82 does not come into contact with the outer surface of the stylus shaft 44 behind the engagement groove 47 along the direction in which the stylus 43 in inserted.

In addition, the first end portion 44a of the stylus shaft 44 is tapered narrower from the engagement groove 47 to the stylus tip 45. This makes it difficult for the engagement projection 82 to come into contact with the outer surface of the first end portion 44a of the stylus shaft 44 in the process of insertion of the stylus 43 into the receptacle 78.

On the other hand, since the first convex portion 85a provided on the receiving portion 77 of the stylus guide 51 comes into contact with the outer peripheral edge portion 46a of the projection portion 46 protruding from the stylus shaft 44, the first convex portion 85a does not come into contact with the stylus shaft 44.

In addition, the first convex portion 85a comes into contact with the outer peripheral edge portion 46a of the projection portion 46 immediately before the first recess 48 provided in the projection portion 46. At the position where the first convex portion 85a comes into contact with the outer peripheral edge portion 46a, the height H of the projection portion 46 is larger than that of the front end of the projection portion 46. For this reason, when the front end of the projection portion 46 enters the receiving portion 77, a gap is produced between the first convex portion 85a and the outer peripheral edge portion 46a of the projection portion 46. This makes it difficult for the first convex portion 85a to come into contact with the outer peripheral edge portion 46a.

As a consequence, the first convex portion 85a does not press the stylus shaft 44 against the inner surface of the concave portion 71 until the first convex portion 85a comes into contact with the outer peripheral edge portion 46a of the projection portion 46 immediately before the first recess 48. For this reason, the second convex portion 85b located on the inner surface of the concave portion 71 is not pressed against the outer surface of the second end portion 44b of the stylus shaft 44.

In spite of the fact that the main body 70 of the stylus guide 51 is provided with the engagement projection 82, first convex portion 85a, and second convex portion 85b which protrude into the concave portion 71, scratches are not easily produced on the outer surface of the stylus shaft 44.

According to the first embodiment, when a stylus thicker than the normal stylus 43 is inserted into the stylus insertion portion 75 of the stylus guide 51, the inner surface of the concave portion 71 of the stylus guide 51 is pressed outward in the radial direction of the stylus. When the stylus presses the inner surface of the concave portion 71, the semi-cylindrical main body 70 elastically deforms in a direction to increase the width of the slit 72, thus absorbing an increase in the diameter of the stylus.

In addition, the plurality of support pieces 66 which support the stylus guide 51 on the holder main body 50 are arranged at intervals in the longitudinal direction of the main body 70. This arrangement makes it easy for the stylus guide 51 to elastically deform as compared with the case in which the stylus guide 51 is held throughout the entire length along the longitudinal direction. It is therefore possible to reliably hold another stylus thicker than the normal stylus 43 with the stylus guide 51.

### Second Embodiment

FIG. 13 shows the second embodiment.

The second embodiment differs from the first embodiment in the position of a first convex portion 85a of a stylus guide 51. As shown in FIG. 13, the first convex portion 85a is located closer to the intermediate portion of the stylus guide 51 along the longitudinal direction than a second convex portion 85b.

For this reason, the first convex portion 85a comes into contact with an outer peripheral edge portion 46a of a projection portion 46 at a position closer to the front end of the projection portion 46 than the second convex portion 85b. This makes the first convex portion 85a clamp and hold a second end portion 44b of a stylus 43 and the projection portion 46 in cooperation with the second convex portion 85b.

### Third Embodiment

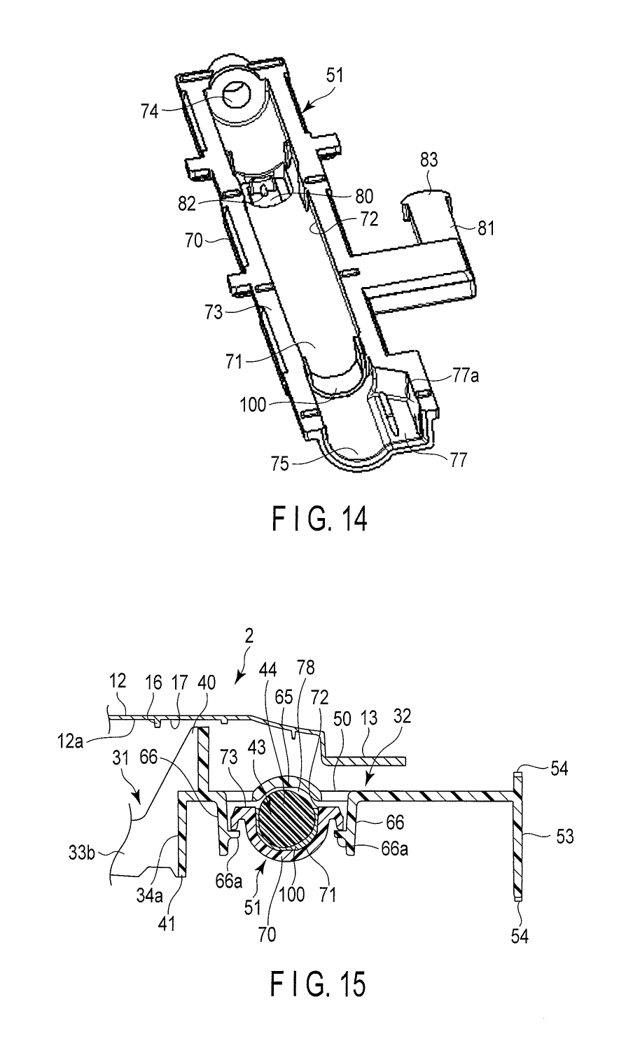

FIGS. 14 and 15 show the third embodiment.

The third embodiment differs from the first embodiment in the arrangement of a portion of a stylus guide 51 which holds a second end portion 44b of a stylus 43. The arrangement of the stylus guide 51 other than this is the same as that in the first embodiment. Therefore, the same reference numbers as in the first embodiment denote the same components in the third embodiment, and a description of them will be omitted.

As shown in FIG. 14, a band-like vibration-proofing member 100 is bonded to the inner surface of a stylus insertion portion 75 of the stylus guide 51. The vibration-proofing member 100 is an example of the second engagement portion, and is formed by, for example, nonwoven fabric more flexible than the stylus 43. The vibration-proofing member 100 is continuous in the circumferential direction of a semi-cylindrical main body 70, and protrudes from the inner surface of the stylus insertion portion 75 into a concave portion 71.

According to the third embodiment, when the stylus 43 is inserted into the stylus insertion portion 75 and an engagement projection 82 of the stylus guide 51 is caught in an engagement groove 47 of the stylus 43, the second end portion 44b of the stylus 43 enters the inside of the vibration-proofing member 100.

In other words, as shown in FIG. 15, the flexible vibration-proofing member 100 is interposed between the second end portion 44b of the stylus 43 and a main body 70 of the stylus guide 51 to fill the gap between the stylus 43 and the stylus guide 51.

This makes it possible to suppress the backlash of the stylus 43 relative to the stylus guide 51 and prevent the production of annoying sounds accompanying the vibration of the stylus 43.

In addition, the vibration-proofing member 100 is formed by nonwoven fabric more flexible than the stylus 43. It is therefore possible to prevent damage on the stylus 43 even if the stylus 43 and the vibration-proofing member 100 rub against each other when the stylus 43 is inserted into the stylus insertion portion 75.

### Fourth Embodiment

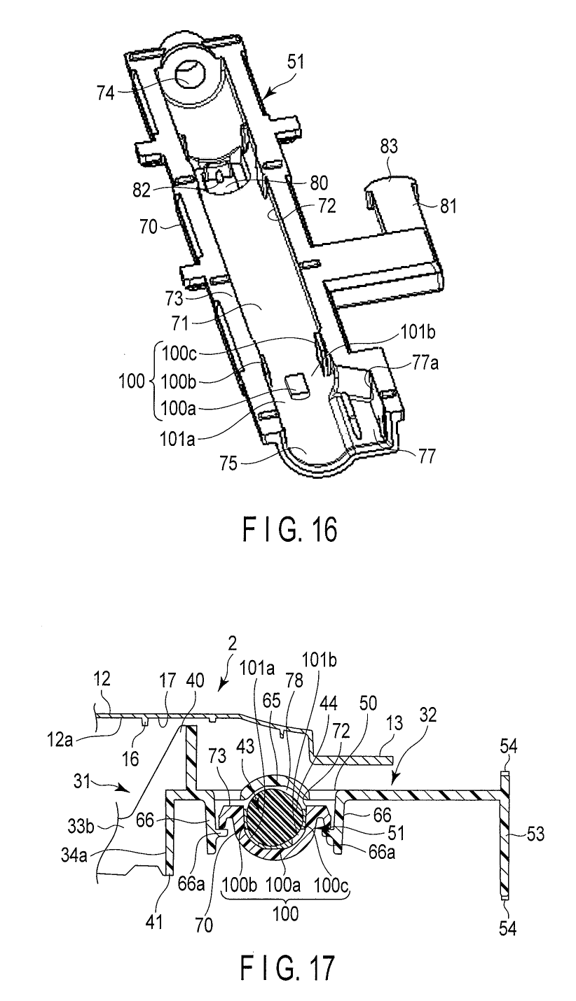

FIGS. 16 and 17 show the fourth embodiment.

In the fourth embodiment, a vibration-proofing member 100 made of nonwoven fabric is divided into three portions, namely a first portion 100a, a second portion 100b, and a third portion 100c. The first to third portions 100a, 100b and 100c are individually bonded to the inner surface of a stylus insertion portion 75, and are arranged at intervals in the circumferential direction of a main body 70. For this reason, a first gap 101a is formed between the first portion 100a and second portion 100b of the vibration-proofing member 100, and a second gap 101b is formed between the first portion 100a and the third portion 100c.

According to this arrangement, the first gap 101a exists between the first portion 100a and second portion 100b of the vibration-proofing member 100, and the second gap 101b exists between the first portion 100a and the third portion 100c. This reduces the contact area between a stylus 43 and the vibration-proofing member 100 by an area corresponding to the first and second gaps 101a and 101b.

As a consequence, in spite of the fact that the vibration-proofing member 100 is provided to suppress the backlash of the stylus 43, the sliding resistance acting on the stylus 43 can be suppressed low. This makes it easy for the user to insert the stylus 43 into the stylus insertion portion 75 or remove the stylus 43 from the stylus insertion portion 75.

### Fifth Embodiment

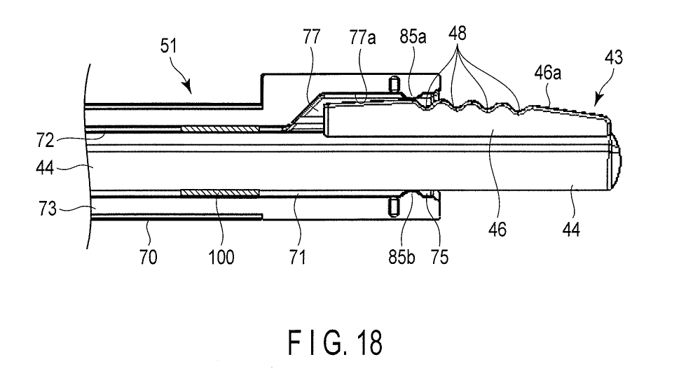

FIG. 18 shows the fifth embodiment.

The fifth embodiment is a combination of the first and third embodiments. The same reference numbers as in the first and third embodiments denote the same components in the fifth embodiment, and a description of them will be omitted.

As shown in FIG. 18, a first convex portion 85a and second convex portion 85b of a stylus guide 51 clamp and hold a second end portion 44b of a stylus shaft 44 and a projection portion 46 at a position immediately before the second end portion 44b of the stylus shaft 44 protrudes outside the stylus guide 51 through a stylus insertion portion 75.

In addition, a vibration-proofing member 100 fills the gap between a stylus 43 and the stylus guide 51 at a position closer to the intermediate portion of the stylus guide 51 along the axial direction than the first and second projection portions 85a and 85b.

According to this arrangement, a stylus guide 51 holds the second end portion 44b of the stylus 43 at two portions spaced apart from each other in the axial direction of the stylus shaft 44. This makes it possible to reliably suppress the backlash of the stylus 43 and prevent the production of annoying sounds accompanying the vibration of the stylus 43.

In the first embodiment, the liquid crystal display device 21 having a handwriting input function is not limited to the arrangement configured to be accommodated in the second housing 20 of the display module 3. For example, it is possible to omit the display module 3 and the keyboard 14 and accommodate the liquid crystal display device 21 in the first housing 4.

In addition, it is possible to hold the first end portion of the stylus with a vibration-proofing member such as a nonwoven fabric member and hold the second end portion and projection portion of the stylus between the first and second convex portions.

The fin-like projection portion of the stylus is not an essential arrangement. For example, it is possible to omit the projection portion from the second end portion of the stylus and directly clamp the second end portion of the stylus between the first and second convex portions.

While certain embodiments have been described, there embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing;
a stylus holder in the housing;
a stylus guide supported by the stylus holder configured to allow a stylus to be inserted or removed along an axial direction; and
a first holder and a second holder on the stylus guide configured to contact an outer surface of the stylus at positions in the axial direction to the stylus.

2. The electronic apparatus of claim 1, wherein the stylus guide comprises a semi-cylindrical body with a slit extending in the axial direction to the stylus, and the first holder and the second holder being configured to protrude from an inner surface of the body.

3. The electronic apparatus of claim 2, wherein the body elastically deforms in a direction to increase a width of the slit.

4. The electronic apparatus of claim 3, wherein the stylus comprises a stylus shaft and a stylus tip, the first holder of the stylus guide being configured to contact the stylus shaft at a position closer to the stylus tip than an intermediate portion of the stylus shaft along an axial direction, and the second holder of the stylus guide being configured to contact the stylus shaft at a position closer to a side opposite to the stylus tip than the intermediate portion of the stylus shaft along the axial direction.

5. The electronic apparatus of claim 4, wherein the second holder comprises a plurality of convex portions protruding from the inner surface of the body configured to hold the stylus shaft from a radial direction to the stylus shaft.

6. The electronic apparatus of claim 5, wherein the stylus shaft comprises a projection portion located on an end opposite to the stylus tip configured to protrude outward along the radial direction of the stylus shaft, and one convex portion contacts an outer edge of the projection portion.

7. The electronic apparatus of claim 4, wherein the second holder comprises a vibration-proofing member on the inner surface of the body of the stylus guide.

8. The electronic apparatus of claim 7, wherein the vibration-proofing member comprises nonwoven fabric.

9. The electronic apparatus of claim 8, wherein the vibration-proofing member is continuous in a circumferential direction to the body.

10. The electronic apparatus of claim 7, wherein the vibration-proofing member is divided into a plurality of portions arranged at intervals in the circumferential direction to the body.

11. An electronic apparatus comprising:
a housing;
a receptacle in the housing;
a guide in the receptacle configured to allow a piece to be inserted or removed along an axial direction, the guide further being configured to move when the piece is inserted or removed; and
a plurality of holders on the guide configured to contact the piece at positions in the axial direction to the piece.

12. The electronic apparatus of claim 11, wherein the receptacle is configured to support the guide so that the guide moves between a first position where the piece is in the housing and a second position where the piece protrudes outside the housing.

13. The electronic apparatus of claim 12, wherein the guide comprises a semi-cylindrical body with a slit extending in an axial direction to the piece, the body being configured to elastically deform to increase a width of the slit.

14. An electronic apparatus comprising:
a housing;
a stylus guide in the housing configured to allow insertion or removal of a stylus; and
a plurality of convex portions on the stylus guide configured to contact the stylus at positions in an axial direction to the stylus.

15. The electronic apparatus of claim 14, wherein the stylus guide comprises a semi-cylindrical body with a slit extending in an axial direction to the stylus, the body being configured to elastically deform to increase a width of the slit.
